(19) United States
(12) Patent Application Publication
(10) Pub. No.: US 2026/0121547 A1
(43) Pub. Date: Apr. 30, 2026

(54) INTEGRATED ON-CHIP/IN-PACKAGE TRANSFORMER DRIVER FOR CAN APPLICATIONS

(71) Applicant: Microchip Technology Incorporated, Chandler, AZ (US)

(72) Inventors: Declan Jordan, Skerries (IE); David Gammie, Chandler, AZ (US)

(21) Appl. No.: 19/069,729

(22) Filed: Mar. 4, 2025

Related U.S. Application Data
(60) Provisional application No. 63/713,020, filed on Oct. 28, 2024.

(51) Int. Cl. H02M 3/335; G01R 31/28; H02M 1/08; H02M 3/337

(52) U.S. Cl. CPC H02M 3/33592; G01R 31/2856; H02M 1/08; H02M 3/3374

(57) ABSTRACT

An integrated circuit (IC) for driving a Controller Area Network (CAN) bus is provided. The IC may include a push-pull transformer having a primary winding split into two halves with a center tap and a secondary winding split into two halves, an energy pump circuit coupled to the primary winding, the energy pump circuit including a first transistor and a second transistor alternately switching to drive the primary winding, at least two diodes coupled to the secondary winding to perform full-wave rectification of an alternating current (AC) voltage induced in the secondary winding, and a smoothing capacitor coupled to the secondary winding to filter the rectified voltage into a steady direct current (DC) output for driving the CAN bus.

### CROSS REFERENCE TO RELATED APPLICATIONS

The present application claims priority to U.S. Provisional Patent Application No. 63/713,020, entitled: Integrated On-Chip/In-Package Transformer Driver for CAN Applications, filed on Oct. 28, 2024, the contents of which are hereby incorporated by reference in their entirety.

### TECHNICAL FIELD

The present disclosure relates generally to a Controller Area Network (CAN) bus, and more specifically to an integrated on-chip/in-package push-pull transformer driver for CAN applications.

### SUMMARY

According to an aspect of one or more examples, there is provided an integrated circuit (IC) for driving a Controller Area Network (CAN) bus. The IC may include a push-pull transformer having a primary winding split into two halves with a center tap, and a secondary winding split into two halves, an energy pump circuit coupled to the primary winding, the energy pump circuit including a first transistor and a second transistor alternately switching to drive the primary winding, at least two diodes coupled to the secondary winding to perform full-wave rectification of an alternating current (AC) voltage induced in the secondary winding, and a smoothing capacitor coupled to the secondary winding to filter the rectified voltage into a steady direct current (DC) output for driving the CAN bus. The energy pump circuit may operate at a switching frequency greater than a data rate of a data stream signal input that drives the primary winding. The IC may also include a current sensing resistor coupled to the secondary winding, the current sensing resistor configured to generate a voltage proportional to a current demand of the CAN bus. Feedback from the current sensing resistor may be used to adjust the power delivery of the energy pump circuit to the push-pull transformer. The smoothing capacitor may be coupled between a CAN High (CANH) bus line and a CAN Low (CANL) bus line. The CAN bus may include at least two termination resistors, each having a resistance of approximately 120 ohms, to match a characteristic impedance of the CAN bus. The CAN bus may include a filter capacitor to attenuate high-frequency noise between the CANH and CANL bus lines. An external testing circuit may be coupled to the IC and configured to test electromagnetic compatibility (EMC) of the CAN bus, the external testing circuit including a common-mode filter to attenuate common-mode noise on the CANH and CANL bus lines, and a bus biasing circuit to stabilize the CAN bus at a reference voltage. The bus biasing circuit may bias the CAN bus to approximately 2.5V using at least two pull-up or pull-down resistors. The push-pull transformer and the energy pump circuit may be integrated on a single chip.

According to an aspect of one or more examples, there is provided a method for driving a Controller Area Network (CAN) bus. The method may include driving a push-pull transformer having a primary winding split into two halves with a center tap, and a secondary winding split into two halves, alternately switching a first transistor and a second transistor of an energy pump circuit to push and pull current through the primary winding, thereby inducing an alternating current (AC) voltage in the secondary winding; rectifying the AC voltage using at least two diodes to produce a pulsating direct current (DC) voltage, and filtering the pulsating DC voltage using a smoothing capacitor to produce a steady DC output for driving the CAN bus. The method may also include receiving a data stream input at the center tap of the primary winding. The data stream input may drive the push-pull transformer. The first and second switching transistors of the energy pump circuit may operate at a switching frequency greater than a data rate of the data stream signal input. The method may also include monitoring a current demand of the CAN bus using a current sensing resistor coupled to the secondary winding. The method may include generating a feedback signal from the current sensing resistor to adjust the power delivery of the energy pump to the push-pull transformer. The method may include biasing CANH and CANL bus lines of the CAN bus to a reference voltage using a bus biasing circuit. The reference voltage may be approximately 2.5V. The method may also include attenuating high-frequency noise on the CAN bus using a filter capacitor coupled between the CANH and CANL bus lines. The termination resistors of the CAN bus may have a resistance of approximately 120 ohms to match a characteristic impedance of the CAN bus. The method may include implementing the push-pull transformer, energy pump circuit, and rectification circuit as part of a single-chip solution.

### BRIEF DESCRIPTION OF DRAWINGS

FIG. 1 shows a circuit diagram of an integrated circuit (IC) for driving a Controller Area Network (CAN) bus according to one or more examples.

FIG. 2 shows a circuit diagram of an IC for driving a CAN bus according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

The Controller Area Network (CAN) bus is a widely adopted communication protocol used in various applications, particularly in automotive and industrial environments. While the CAN bus offers numerous advantages, it is not without its challenges, particularly concerning common mode noise, high voltage transients, and electrostatic discharge (ESD) events.

A CAN bus architecture may employ a high side PMOS and a low side NMOS transistor for signal driving. Due to the physical differences between these two types of transistors, they may switch on and off at different rates. This rate mismatch may lead to imbalances in current sourcing and sinking, resulting in fluctuations in the common mode voltage. Such noise may contribute to electromagnetic interference (EMI) and pose compliance challenges with ISO standards, potentially compromising the reliability of the system.

To mitigate the effects of electrical noise, large high voltage transistors and Zener stacks may be implemented in CAN bus designs. These components may handle large common mode voltages and protect against ESD events. However, the inclusion of these high voltage transistors and Zener stacks may increase the overall die size and manufacturing costs, making it an inefficient solution from both a space and economic standpoint.

While existing solutions may address some aspects of the challenges faced by CAN bus systems, they fall short in providing a balance of performance, size, and cost. Therefore, there exists a need for a method or apparatus that effectively resolves one or more of these issues while minimizing the physical footprint and overall expense associated with CAN bus implementations.

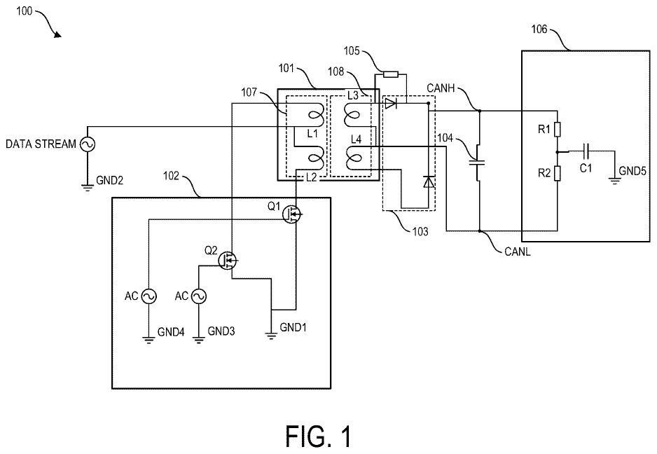

FIG. 1 shows a circuit diagram of an integrated circuit (IC) 100 for driving a Controller Area Network (CAN) bus according to one or more examples. As shown in FIG. 1, the IC 100 may include a push-pull transformer 101, an energy pump circuit 102, a rectification circuit 103, a smoothing capacitor 104, a current sensing resistor 105, and a CAN bus 106.

The push-pull transformer 101 may include a primary winding 107 split into two halves (e.g., L1 and L2) with a center tap, and a secondary winding 108 split into two halves (e.g., L3 and L4). According to one or more examples, a data stream signal having a data rate may be coupled to the center tap of the push-pull transformer 101. The center tap may be the halfway point of the primary winding 107 (e.g., contact point in the middle of L1 and L2). The data stream signal may be transmitted by a microcontroller. The data stream signal may contain data to be output to the CAN bus 106. The data stream signal may be an input voltage provided to the center tap of the push-pull transformer 101. The primary winding 107 may be charged by the data stream signal and the energy pump circuit 102, and this may transfer energy to the secondary winding 108 via electromagnetic induction. The energy pump circuit 102 may be coupled to the primary winding 107 of the push-pull transformer 101. The energy pump circuit 102 may include a first transistor (e.g., Q1) and a second transistor (e.g., Q2). The energy pump circuit 102 may include first and second AC sources respectively coupled to the first and second transistors Q1 and Q2. According to one or more examples, the first and second transistors Q1 and Q2 may be field-effect transistors (FETs). The first transistor Q1 may have a source terminal coupled to ground GND1, a gate terminal coupled to a positive terminal of the first AC source, and a drain terminal coupled to the push-pull transformer 101 (e.g., L2). The second transistor Q2 may have a source terminal coupled to ground GND1, a gate terminal coupled to a positive terminal of the second AC source, and a drain terminal coupled to the push-pull transformer 101 (e.g., L1). A negative terminal of first AC source may be coupled to ground GND4, and a negative terminal of the second AC source may be coupled to ground GND3.

According to one or more examples, an AND gate may be used with AC signals from the first and second AC sources to control the first and second transistors Q1 and Q2. For example, when the data stream signal is low (e.g., binary 0), the output of the AND gate may be 0, and neither of the first and second transistors Q1 and Q2 turn on. When the data stream signal is high (e.g., binary 1), the output of the AND gate may be determined by the AC signals (e.g., output of the AND gate is 1 when the AC signal is 1, and output of the AND gate is 0 when the AC signal is 0). The first and second transistors Q1 and Q2 may toggle at a switching frequency (Fsw). According to one or more examples, the data stream signal may be buffered and connected to the center tap of the push-pull transformer 101. For example, when the data stream signal is low (e.g., binary 0), a voltage at the center tap of the push-pull transformer 101 may be 0. Even though the first and second transistors Q1 and Q2 toggle at the switching rate Fsw, current may not flow through the push-pull transformer 101 because the voltage differential between the center tap (e.g., 0V) and ground (e.g., 0V) is zero. When the data stream signal is high (e.g., binary 1), the voltage at the center tap of the push-pull transformer 101 may be non-zero (e.g., 1.8V, 3.3V, or 5V). As the first and second transistors Q1 and Q2 toggle at the switching rate Fsw, current may flow through the push-pull transformer 101 from the center tap to ground because the voltage differential between the center tap and ground is non-zero.

The first and second transistors Q1 and Q2 may alternately drive current through the primary winding 107, causing a changing magnetic field in the magnetic core of the push-pull transformer 101. This may induce a voltage in the secondary winding 108, supplying power to the CAN bus 106. The first and second transistors Q1 and Q2 may operate at a switching frequency (Fsw) greater than the data rate of the data stream signal, meaning the push-pull transformer 101 goes through multiple switching cycles per bit of data transmitted, providing continuous power to the CAN bus 106. For example, the data stream signal may initially be transmitted to the center tap of the push-pull transformer 101. At a first half cycle of the switching frequency Fsw, the first transistor Q1 may be turned on, which allows current to flow through L2 and charge L2. The secondary winding 108 (e.g., L3 and L4) may then be charged due to an induction of voltage. The direction of the current may be clockwise and, as a result, a first diode of the rectification circuit 103 becomes forward biased and a second diode of the rectification circuit 103 becomes reversed biased. The voltage after the diodes may be in pulsating form. At a second half cycle of the switching frequency Fsw, the second transistor Q2 may be turned on, which allows current to flow through L1 and charge L1. The secondary winding 108 (e.g., L3 and LA) may be charged due to an induction of voltage. The direction of the current may be counter-clockwise and, as a result, the second diode of the rectification circuit 103 becomes forward biased. The voltage after the diodes may be in pulsating form.

The rectification circuit 103 may include at least two diodes. The diodes may be coupled to the secondary winding 108 of the push-pull transformer 101 to perform full-wave rectification of an AC voltage induced in the secondary winding 108. An orientation of the diodes may ensure that the current induced in the secondary winding 108 of the push-pull transformer 101 flows in to CANH and out of CANL. For example, an anode of a first diode of the rectification circuit 103 may be coupled to the secondary winding 108 (e.g., L3) and a cathode of the first diode may be coupled to CANH. An anode of a second diode of the rectification circuit 103 may be coupled to the secondary winding 108 (e.g., L4) and a cathode of the second diode may be coupled to CANH. The rectification circuit 103 may convert the AC voltage from the secondary windings 108 into a direct current (DC) voltage. After rectification, the DC voltage may be in pulsating form that varies over time rather than being steady. The smoothing capacitor 104 may be coupled to the secondary winding 108. The smoothing capacitor 104 may smooth or stabilize the pulsating DC voltage after the diodes. The smoothing capacitor 104 may reduce the ripple in the pulsating DC voltage. The smoothing capacitor 104 may convert the pulsating DC voltage after the diodes into a steady DC voltage. The steady DC voltage may be the desired output voltage to drive the CAN bus 106.

The current sensing resistor 105 may be used to monitor the current flowing through it. The current sensing resistor 105 may be coupled in parallel with a diode of the rectification circuit 103. The current sensing resistor 105 may produce a small voltage proportional to the current flowing through it. This voltage may be measured to determine the current demand on the CAN bus 106, especially in the dominant state where the CAN bus 106 requires more current, or other information from the CAN bus 106. Feedback from the current sensing resistor 105 may be used to adjust the power delivery (e.g., alternating current delivered to the push-pull transformer 101) or for system monitoring purposes, ensuring that the primary side can provide adequate current during high-demand periods (like when the CAN bus 106 is in a dominant state). According to one or more examples, a diode (not shown in FIG. 1) may be positioned in series with the current sensing resistor 105 to prevent current from entering the current sensing resistor 105 during a write operation to the CAN bus 106.

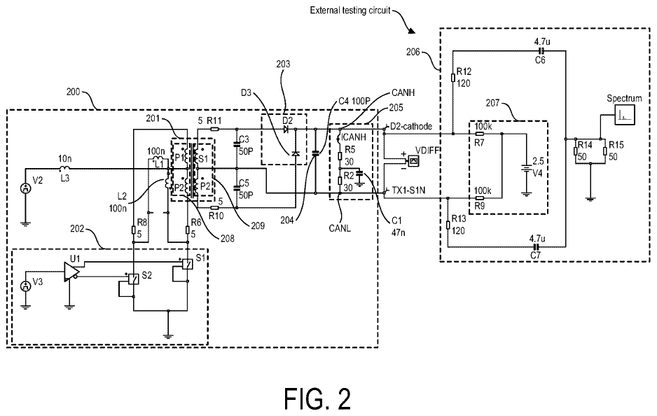

The CAN bus 106 may include termination resistors (e.g., R1 and R2) and a filter capacitor (e.g., C1). The termination resistors R1 and R2 may have a resistance of approximately 120 Ohms to match the characteristic impedance of the CAN bus 106. The termination resistors R1 and R2 may prevent signal reflections and ensure proper communication. The filter capacitor C1 may be used for EMI filtering. The filter capacitor C1 may remove high-frequency noise on the CAN bus lines, CANH and CANL, ensuring clean signal transmission. According to one or more examples, the IC 100 may also include a bus biasing circuit and a common-mode filter, as described below in FIG. 2.

FIG. 2 shows a circuit diagram of an IC 200 for driving a CAN bus according to one or more examples. As shown in FIG. 2, the IC 200 may include a push-pull transformer 201, an energy pump circuit 202, a rectification circuit 203, a smoothing capacitor 204, and the CAN bus 205.

Similar to the push-pull transformer 101 in FIG. 1, the push-pull transformer 201 may include a primary winding 208 split into two halves (e.g., P1 and P2) with a center tap, and a secondary winding 209 split into two halves (e.g., S1 and S2). The energy pump circuit 202 may be coupled to the primary winding 208. The energy pump circuit 202 may include a first transistor (e.g., S1) and a second transistor (e.g., S2). The energy pump circuit 202 may also include AC signal V3, and an inverting op-amp U1. The first and second transistors S1 and S2 may alternately switch current through the primary winding 208 to generate an alternating magnetic field. This switching may be controlled by the inverting op-amp U1 and AC signal V3, generating a high-frequency oscillating signal. According to one or more examples, AC signal V2 may be coupled to the center tap of the push-pull transformer 201. The center tap may be the halfway point of the two halves of the primary winding 208 (e.g., contact point in the middle of P1 and P2). According to one or more examples, AC signal V2 may be a 5V 5 MHz square wave representing data. According to one or more examples, AC signal V3 may be a control signal for the first and second transistors S1 and S2. The first and second transistors S1 and S2 may operate at a switching frequency (Fsw) greater than a data rate of the AC signal V2. As discussed above in FIG. 1, when an alternating current flows through the primary winding 208, it may generate an alternating magnetic field around it. The alternating magnetic field around the primary winding 208 may travel through the magnetic core of the push-pull transformer 201 and link to the secondary winding 209, inducing a voltage in the secondary winding 209.

Similar to the rectification circuit 103 in FIG. 1, the rectification circuit 203 may include at least two diodes (e.g., D2 and D3). The rectification circuit 203 may perform full-wave rectification of the AC voltage induced in the secondary winding 209, converting the AC voltage into a direct current (DC) voltage. The rectified DC voltage may be smoothed by capacitors C3 (50 pF) and C5 (50 pF) to produce a steady DC voltage output. Resistor R11 may be a series resistor that helps to limit inrush current and prevent excessive power dissipating during startup or signal spikes. The smoothing capacitor 204 (e.g., C4 (100 pF)) may be coupled in parallel with the secondary winding 209. The smoothing capacitor 204 may further smooth or stabilize the rectified DC voltage after the diodes.

Similar to the CAN bus 106 in FIG. 1, the CAN bus 205 may include termination resistors (e.g., R2 and R5 (30 Ohms each)) and a filter capacitor (e.g., C1 (47 nF)). The termination resistors R2 and R5 may have a resistance of approximately 120 Ohms to match the characteristic impedance of the CAN bus 205. The termination resistors R2 and R5 may prevent signal reflections and ensure proper communication. The filter capacitor C1 may remove high-frequency noise on the CAN bus lines, ensuring clean signal transmission.

According to one or more examples, the IC 200 may include a differential signal measurement (VDIFF). The IC 200 may connect to the CAN bus via the differential signals CANH and CANL. These signals may be used for communication between nodes in the network. The IC 200 may use differential signaling, where the voltage difference between CANH and CANL carries the data. VDIFF may be the differential voltage measured between the CANH and CANL lines. VDIFF may be used for monitoring signal integrity and ensuring the differential levels meet the requirements for CAN communication.

According to one or more examples, an external testing circuit may be coupled to the IC 200 to test compliance with ISO Standards pertaining to electromagnetic compatibility (EMC). The external testing circuit may include a common-mode filter 206 and a bus biasing circuit 207.

The common-mode filter 206 may improve the IC's 200 noise immunity by filtering out common-mode noise while preserving the integrity of the differential signals, making it better for testing or operation in noisy environments. The common-mode filter 206 may include resistors (e.g., R12 and R13 (120 Ohms each), R14 and R15 (50 Ohms each)), capacitors (e.g., C6 and C7 (47 Ohms each)), and a spectrum measurement node. The resistors may provide proper termination for the differential bus lines. As discussed above, termination resistors may prevent signal reflections on the bus, which can lead to signal degradation and communication errors. The resistors may also play a role in balancing the impedance of the bus lines, ensuring that the CAN bus adheres to standard impedance levels (typically 60 Ohms for a CAN bus). The capacitors may act as high-frequency filters. The capacitors may remove high-frequency noise from both CANH and CANL lines that could result from external interference or coupling from nearby circuits. The capacitors may be tuned to filter out noise components common to both bus lines (common-mode noise), without affecting the differential signals that carry the actual data. The spectrum node may be used for testing and monitoring the effectiveness of the common-mode filter 206. The spectrum node may allow for the measurement of common-mode noise on the bus, helping engineers to validate that the common-mode filter 206 is working correctly and that the bus is free from noise that can impact communication.

The bus biasing circuit 207 may be part of the common-mode filter 206. The bus biasing circuit 207 may ensure that the bus lines are held at a stable voltage level when no dominant signal is present, preventing floating lines or noise-induced errors. The bus biasing circuit 207 may include resistors (e.g., R7 and R9 (100 kOhms each)) and a reference voltage (e.g., V4 (2.5V)). The resistors R7 and R9 may create a weak pull-up and pull-down for the bus lines to the reference voltage V4. This may ensure the lines do not float and are biased toward a known voltage level when no dominant signal is being transmitted (recessive state). This biasing may help to prevent noise or instability when the bus is idle, which may be beneficial for proper bus operation, particularly in environments with significant electromagnetic interference (EMI). The reference voltage V4 may act as a midpoint for the bus lines, setting the idle voltage level (e.g., at 2.5V). This may ensure that when the bus is not actively driven, both CANH and CANL lines are at a defined level, reducing the changes of noise interference or erroneous voltage levels.

Various examples have been disclosed herein, in connection with the above description and the drawings. It will be understood that it would be unduly repetitious to literally describe and illustrate every combination and subcombination of these examples. Accordingly, all examples can be combined in any way or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. An integrated circuit (IC) for driving a Controller Area Network (CAN) bus, comprising:
a push-pull transformer having a primary winding split into two halves with a center tap, and a secondary winding split into two halves;
an energy pump circuit coupled to the primary winding, the energy pump circuit comprising a first transistor and a second transistor alternately switching to drive the primary winding;
at least two diodes coupled to the secondary winding to perform full-wave rectification of an alternating current (AC) voltage induced in the secondary winding; and
a smoothing capacitor coupled to the secondary winding to filter the rectified voltage into a steady direct current (DC) output for driving the CAN bus.

2. The IC of claim 1, wherein the energy pump circuit operates at a switching frequency greater than a data rate of a data stream signal input that drives the primary winding.

3. The IC of claim 1, further comprising a current sensing resistor coupled to the secondary winding, the current sensing resistor configured to generate a voltage proportional to a current demand of the CAN bus.

4. The IC of claim 3, wherein feedback from the current sensing resistor is used to adjust the power delivery of the energy pump circuit to the push-pull transformer.

5. The IC of claim 1, wherein the smoothing capacitor is coupled between a CAN High (CANH) bus line and a CAN Low (CANL) bus line.

6. The IC of claim 1, wherein the CAN bus includes at least two termination resistors, each having a resistance of approximately 120 ohms, to match a characteristic impedance of the CAN bus.

7. The IC of claim 6, wherein the CAN bus includes a filter capacitor to attenuate high-frequency noise between the CANH and CANL bus lines.

8. The IC of claim 1, wherein an external testing circuit is coupled to the IC and configured to test electromagnetic compatibility (EMC) of the CAN bus, the external testing circuit including:
a common-mode filter to attenuate common-mode noise on the CANH and CANL bus lines, and
a bus biasing circuit to stabilize the CAN bus at a reference voltage.

9. The IC of claim 8, wherein the bus biasing circuit is to bias the CAN bus to approximately 2.5V using at least two pull-up or pull-down resistors.

10. The IC of claim 1, wherein the push-pull transformer and the energy pump circuit are integrated on a single chip.

11. A method for driving a Controller Area Network (CAN) bus using an integrated circuit (IC), comprising:
driving a push-pull transformer having a primary winding split into two halves with a center tap, and a secondary winding split into two halves;
alternately switching a first transistor and a second transistor of an energy pump circuit to push and pull current through the primary winding, thereby inducing an alternating current (AC) voltage in the secondary winding;
rectifying the AC voltage using at least two diodes to produce a pulsating direct current (DC) voltage; and
filtering the pulsating DC voltage using a smoothing capacitor to produce a steady DC output for driving the CAN bus.

12. The method of claim 11, further comprising receiving a data stream input at the center tap of the primary winding, wherein the data stream input drives the push-pull transformer.

13. The method of claim 11, wherein the first and second switching transistors of the energy pump circuit operate at a switching frequency greater than a data rate of the data stream signal input.

14. The method of claim 11, further comprising monitoring a current demand of the CAN bus using a current sensing resistor coupled to the secondary winding.

15. The method of claim 14, comprising generating a feedback signal from the current sensing resistor to adjust the power delivery of the energy pump to the push-pull transformer.

16. The method of claim 11, comprising biasing CANH and CANL bus lines of the CAN bus to a reference voltage using a bus biasing circuit.

17. The method of claim 16, wherein the reference voltage is approximately 2.5V.

18. The method of claim 11, further comprising attenuating high-frequency noise on the CAN bus using a filter capacitor coupled between the CANH and CANL bus lines.

19. The method of claim 11, wherein the termination resistors of the CAN bus have a resistance of approximately 120 ohms to match a characteristic impedance of the CAN bus.

20. The method of claim 11, comprising implementing the push-pull transformer, energy pump circuit, and rectification circuit as part of a single-chip solution.
